(19) United States
(12) Patent Application Publication
(10) Pub. No.: US 2021/0127507 A1
(43) Pub. Date: Apr. 29, 2021

(54) FLEXIBLE DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Wei WANG, Wuhan (CN); Pinquan XU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/610,923

(22) PCT Filed: Apr. 24, 2019
(86) PCT No.: PCT/CN2019/083974

§ 371 Date: Nov. 5, 2019

(30) Foreign Application Priority Data
Dec. 18, 2018 (CN) 201811555158.X

(51) Int. Cl. H05K 5/00

(52) U.S. Cl. CPC H05K 5/0017

(57) ABSTRACT

A flexible display device includes a display area, a first sector region, a first linear region, a second sector region, a second linear region, and a bonding region. A first signal line and a second signal line are disposed in the display area. A signal is transmitted through the first signal line and the second signal line disposed in a metal layer in the first sector region, the first linear region, the second sector region, the second linear region up to a metal layer in the bonding region. An overall resistance value of the first signal line is greater than an overall resistance value of the second signal line. Therefore, the problem of a difference in signal transmission speed and a difference in signal loss due to large resistant differences between different signal lines is effectively resolved.

### BACKGROUND

### 1. Field of the Disclosure

The present disclosure relates to the display technology, and more particularly, to a flexible display device.

### 2. Description of the Related Art

A display screen with a narrow bezel has a high screen ratio, which is favored by users and becomes the focus of research and development for display panel enterprises. However, constraint to the layout of the peripheral circuit, it is somehow difficult to design a display panel with a narrow bezel in some areas.

Specifically, for example, a metal routing that connects a pixel control circuit electrode and a driving chip is disposed between a display area and the driving chip in a display panel. These metal routing can be roughly divided into several areas according to shapes such as a sector region 1: a signal routing in the display area is led out; a linear region 1: a signal routing in the sector region 1 extends downward. The sector region 1 is a flexible bending region, which is bent along a bending line. A sector region 2, a linear region 2, a bonding region, and a flexible printed circuit board followed by the flexible bending region are bent by the flexible bending region. One or more portions of the flexible bending region, the sector region 2, the linear region 2, the bonding region, and the flexible printed circuit are located below the display area to reduce the size of the lower frame to some extent.

However, the sector region 1 in the structure is still on the same plane as the display area stays, which also increases the size of the lower frame. Therefore, how to reduce the width of the sector region 1 becomes crucial to fabricate the lower bezel.

Further, for the structure of the sector region 1 of the related art, the signal routing includes a single metal layer. So the width of the sector region 1 is mainly determined by the width of the signal routing in the metal layer and the pitch of a signal line adjacent to the signal routing. In order to reduce the width of the sector region 1, a new layout of two-layer metal is developed in the industry. The layout of two-layer metal reduces the pitch of two adjacent signal lines. Therefore, the effective width of the sector region 1 can be effectively reduced.

Further, as for the layout of two-layer metal for such a sector region, the first metal layer and the second metal layer are generally extensions of two metal film layers in a driving array. For example, a first metal layer and a gate metal layer in a driving array are shared. A second metal layer and an upper plate of a capacitor are shared. When the materials of the first metal layer and the second metal layer are different (for example, the first metal layer is fabricated by molybdenum (Mo), and the second metal layer is fabricated by composite material Ti—Al—Ti, the resistivity of the two metal layers differs a lot, which leads to two problems of signal transmission through adjacent signal lines using different metal layers as follows:

1. The signal transmission rates of adjacent signal lines are different;

2. The losses of voltage generated by adjacent signal lines are different.

These factors may cause abnormal display on the display panel. Therefore, it is necessary to develop a new type of flexible display device to deal with the defects in the related art.

### SUMMARY

### Technical Problem

The present disclosure proposes a flexible display device to resolve the problem that a difference of the resistances of the double-layer metal signal routings in a peripheral circuit structure in the related art.

### Technical Solution

According to the present disclosure, a flexible display device comprises a display area, a first sector region, a first linear region, a second sector region, a second linear region, and a bonding region. A first signal line and a second signal line are disposed in the display area. A signal is transmitted through the first signal line and the second signal line disposed in a metal layer in the first sector region, the first linear region, the second sector region, the second linear region up to a metal layer in the bonding region. A first metal layer and a second metal layer are arranged on upper and lower layers of the first sector region, upper and lower layers of the first linear region, upper and lower layers of the second sector region, and upper and lower layers of the second linear region. An overall resistance value R1 indicates a sum of the first metal layer or the second metal layer in the first sector region, the first linear region, the second sector region, the second linear region, and the bonding region where the first signal line is arranged. An overall resistance value R2 indicates a sum of the first metal layer or the second metal layer in the first sector region, the first linear region, the second sector region, the second linear region, and the bonding region where the second signal line is arranged. A difference between the overall resistance value R1 and the overall resistance value R2 is within 15% of the overall resistance value R1 or within 15% of the overall resistance value R2.

Furthermore, the first signal line and the second signal line are metal routings that connect a pixel control circuit electrode and a driving chip between the display area and the driving chip.

Furthermore, the first signal line and the second signal line are disposed on different metal layers in the first sector region.

Furthermore, the first signal line and the second signal line are disposed on different metal layers in the second sector region.

Furthermore, the first signal line and the second signal line are disposed on different metal layers in the second linear region.

Furthermore, the first signal line and the second signal line are disposed on an identical metal layer in the first linear region.

Furthermore, the first metal layer and the second metal layer are arranged in an up-and-down manner in the first sector region.

Furthermore, the first metal layer and the second metal layer are arranged in an up-and-down manner in the second sector region.

Furthermore, the first metal layer and the second metal layer are arranged in an up-and-down manner in the first linear region and the second sector region.

Furthermore, the first metal layer is fabricated by molybdenum (Mo) or composite material Ti—Al—Ti. the second metal layer is fabricated by Mo or composite material Ti—Al—Ti. A material for the first metal layer is different from a material for the second metal layer.

### Advantageous Effect

The flexible display device of the present disclosure adopts a combined arrangement so that different signal lines are arranged in different layers of metal routing layers through different combined arrangements. The sum of the resistance values of the different or the same metal layers disposed in these different regions is approximately equal, or the resistant differences are within an acceptable range. Therefore, the problem of a difference in signal transmission speed and a difference in signal loss due to large resistant differences between different signal lines is effectively resolved.

### BRIEF DESCRIPTION OF THE DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 illustrates a schematic diagram of a flexible display panel according to an embodiment of the present disclosure.

FIG. 2 illustrates a cross sectional view of schematic diagram of metal layers arrangement in the sector region of the flexible display panel shown in FIG. 1.

FIG. 3 illustrates two adjacent signals of the flexible display panel shown in FIG. 1.

### DETAILED DESCRIPTION OF THE EMBODIMENTS

Examples of the described embodiments are given in the accompanying drawings, wherein the identical or similar reference numerals constantly denote the identical or similar elements or elements having the identical or similar functions. The specific embodiments described with reference to the attached drawings are all exemplary and are intended to illustrate and interpret the present disclosure, which shall not be construed as causing limitations to the present disclosure.

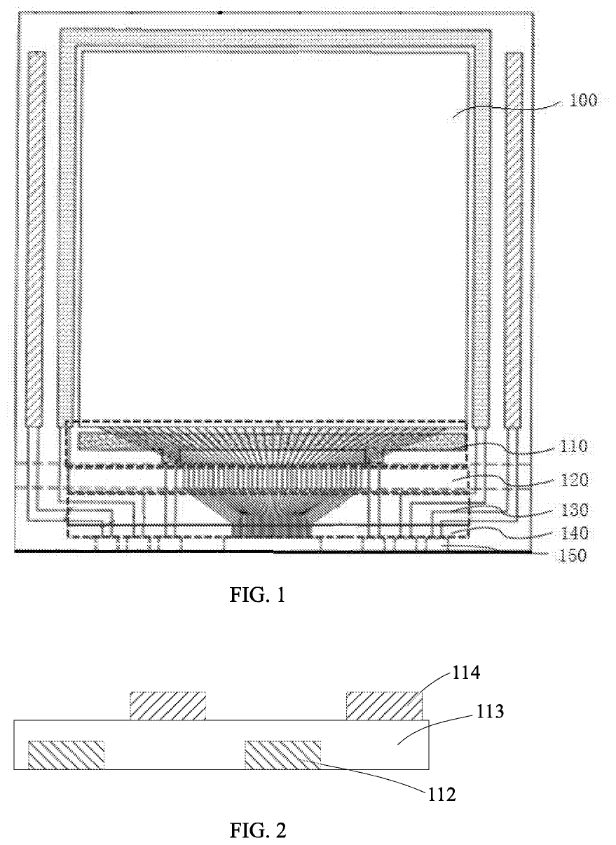

As illustrated in FIG. 1, a flexible display device is proposed by the present disclosure. The flexible display device includes a display area 100, a first sector region 110, a first linear region 120, a second sector region 130, a second linear region 140, and a bonding region 150.

As illustrated in FIG. 2, a first metal layer 112 and a second metal layer 114 are arranged on upper and lower layers of the first sector region, upper and lower layers of the first linear region, upper and lower layers of the second sector region, and upper and lower layers of the second linear region. Specifically, the first metal layer is fabricated by molybdenum (Mo), and the second metal layer is fabricated by composite metal TiAlTi.

Further, a plurality of signal lines are disposed in the display area 100. The signal lines may be metal routings that connect the pixel control circuit electrodes and the driving chip between the display area and the driving chip. Each of the signal lines includes a metal layer disposed in the first sector region, the first linear region, the second sector region up to the second linear region and the metal layer in the bonding region 150.

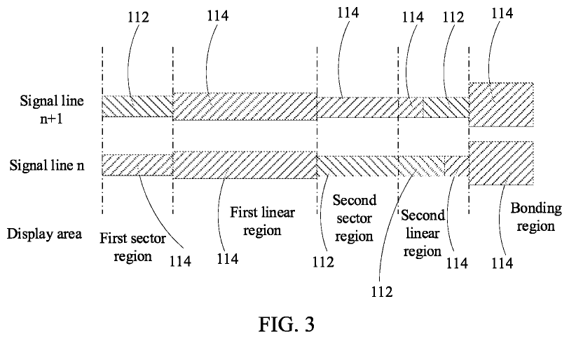

Two adjacent signal line n and signal line (n+1) from these signal lines are taken as an example in one embodiment. Referring to FIG. 3, in the first sector region 110, the signal line n is disposed the second metal layer 114 and the signal line (n+1) is disposed in the first metal layer 112. So the resistance of the signal linen in the first sector region 110 is smaller than the resistance of the signal line (n+1).

The signal line (n+1) and the signal linen are in the same metal layer in the first linear line region 120. Specifically, the signal line (n+1) and the signal line n may be disposed in a first or two metal layer. The figure illustrates the second metal layer 114. The resistance of the signal line (n+1) is the same as the resistance of the signal line n.

The signal line n is disposed in the first metal layer 112. The signal line (n+1) is disposed in the second metal layer 114. So the resistance of the signal linen is greater than the resistance of the signal line (n+1) in the second sector region 130.

In the second linear region 140, the signal line n and the signal line (n+1) alternately are in the first metal layer 112 and the second metal layer 114 except that different metal layers are disposed in the corresponding upper and lower layers. In the bonding region 150, the signal line n and the signal line (n+1) are both disposed in the same metal layer, such as the second metal layer 114, as illustrated in FIG. 3.

Due to the metal layers for the first sector region 110, the first linear region 120, the second sector region 130, the second linear region 140, and the bonding region 150, the difference in resistance between an overall resistance value R1 and an overall resistance value R2 between the signal line n and the signal line (n+1) is equal or close.

The flexible display device of the present disclosure adopts a combined arrangement so that different signal lines are arranged in different layers of metal routing layers through different combined arrangements. The sum of the resistance values of the different or the same metal layers disposed in these different regions is approximately equal, or the resistant differences are within an acceptable range. Therefore, the problem of a difference in signal transmission speed and a difference in signal loss due to large resistant differences between different signal lines is effectively resolved.

In conclusion, the flexible display device of the present disclosure adopts a combined arrangement so that different signal lines are arranged in different layers of metal routing layers through different combined arrangements. The sum of the resistance values of the different or the same metal layers disposed in these different regions is approximately equal, or the resistant differences are within an acceptable range. Therefore, the problem of a difference in signal transmission speed and a difference in signal loss due to large resistant differences between different signal lines is effectively resolved.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A flexible display device, comprising a display area, a first sector region, a first linear region, a second sector region, a second linear region, and a bonding region; a first signal line and a second signal line being disposed in the display area; a signal being transmitted through the first signal line and the second signal line disposed in a metal layer in the first sector region, the first linear region, the second sector region, the second linear region up to a metal layer in the bonding region;
a first metal layer and a second metal layer arranged on upper and lower layers of the first sector region, upper and lower layers of the first linear region, upper and lower layers of the second sector region, and upper and lower layers of the second linear region;
wherein an overall resistance value R1 indicates a sum of the first metal layer or the second metal layer in the first sector region, the first linear region, the second sector region, the second linear region, and the bonding region where the first signal line is arranged; an overall resistance value R2 indicates a sum of the first metal layer or the second metal layer in the first sector region, the first linear region, the second sector region, the second linear region, and the bonding region where the second signal line is arranged; a difference between the overall resistance value R1 and the overall resistance value R2 is within 15% of the overall resistance value R1 or within 15% of the overall resistance value R2.

2. The flexible display device of claim 1, wherein the first signal line and the second signal line are metal routings that connect a pixel control circuit electrode and a driving chip between the display area and the driving chip.

3. The flexible display device of claim 1, wherein the first signal line and the second signal line are disposed on different metal layers in the first sector region.

4. The flexible display device of claim 1, wherein the first signal line and the second signal line are disposed on different metal layers in the second sector region.

5. The flexible display device of claim 1, wherein the first signal line and the second signal line are disposed on different metal layers in the second linear region.

6. The flexible display device of claim 1, wherein the first signal line and the second signal line are disposed on an identical metal layer in the first linear region.

7. The flexible display device of claim 1, wherein the first metal layer and the second metal layer are arranged in an up-and-down manner in the first sector region.

8. The flexible display device of claim 1, wherein the first metal layer and the second metal layer are arranged in an up-and-down manner in the second sector region.

9. The flexible display device of claim 1, wherein the first metal layer and the second metal layer are arranged in an up-and-down manner in the first linear region and the second sector region.

10. The flexible display device of claim 1, wherein the first metal layer is fabricated by molybdenum (Mo) or composite material Ti—Al—Ti; the second metal layer is fabricated by Mo or composite material Ti—Al—Ti; a material for the first metal layer is different from a material for the second metal layer.
